(19) United States
(12) Patent Application Publication
(10) Pub. No.: US 2004/0147131 A1
(43) Pub. Date: Jul. 29, 2004

(54) Plasma processing apparatus and plasma processing method

(76) Inventors: Hiroyuki Kitsunai, Niihari-gun (JP); Junichi Tanaka, Tsuchiura-shi (JP); Hideyuki Yamamoto, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/373,097

(22) Filed: Feb. 26, 2003

(30) Foreign Application Priority Data
Jan. 29, 2003 (JP) 2003-020341

(51) Int. Cl. H01L 21/302; H01L 21/461

(52) U.S. Cl. 438/710

(57) ABSTRACT

A plasma processing apparatus comprising a processing chamber 1 for providing a plasma process to a wafer 2 and a control unit 10, wherein the processing chamber 1 comprises plasma status detecting means 8 and 9 for detecting the processing status in the chamber and outputting plural output signals; and the control unit 10 comprises a function 13 to store data related to past wafer processing results and the plasma status detection data obtained during that past wafer processing, and a relational expression relating the two data; a function 11 to compute the prediction on the process result based on data transmitted from the plasma status detecting means 8, 9 and the relational expression; and a function 12 to evaluate the status of the processing chamber based on said computed prediction of the processing result, according to which the prediction is computed after processing the wafer based on the relational expression. Thereby, the status of the processing chamber is monitored.

### FIELD OF THE INVENTION

The present invention belongs to the field of semiconductor fabrication. Especially, the present invention relates to a plasma processing apparatus and a plasma processing method capable of realizing repeatability of processing results when providing plasma processing to wafers in a semiconductor manufacturing apparatus.

### DESCRIPTION OF THE RELATED ART

Along with the recent advancement in the integration of semiconductor devices, circuit patterns have become extremely minute, and the required accuracy of the processing dimension has become very strict. For example, if the processing dimension is dispersed by as little as 10 nm or less, the dispersion may cause the device to be defective. Under such circumstances, it is important that the processing status of the plasma process has repeatability

If reaction products are deposited as residue on the internal walls of the processing chamber in the plasma processing apparatus, the wafer processing status may change, which may influence the processing result, making it impossible for the repeatability of the processing status to be maintained. Thus, if the amount of residual reaction products within the processing chamber is dispersed per process, the result of the process is also dispersed. Especially when the residual products are removed completely by maintenance etc., the processing result may be varied greatly after the maintenance.

Conventionally, in order to cope with such dispersion of plasma processing results, there has been attempts to recover the status of the processing chamber by seasoning processes. Such conventional methods involve cleaning the interior of the processing chamber with plasma, then performing etching of a dummy wafer under a condition similar to etching the actual product, to thereby bring the status of the internal walls of the processing chamber close to when continuous processing has been performed (refer for example to patent document 1).

According to another conventional method, the plasma processing chamber of the plasma processing apparatus is equipped with various sensors, and by monitoring the fluctuation of the output signals from these various sensors, the changes in the processing status of the plasma processing apparatus are detected. The conventional method for monitoring the processing status of the plasma processing apparatus utilizes multivariate analysis so as to correspond to the various detection data output from the plural sensors (refer for example to patent document 2).

Patent Document 1

Japanese Patent Laid-Open Publication No. 2002-110642

Patent Document 2

Japanese Patent Laid-Open Publication No. 2002-25981

However, the example disclosed in patent document 1 does not consider when the processing chamber status has recovered during the seasoning process. In other words, there is no way of detecting when the seasoning process should be terminated. If the seasoning time is too short, the amount of reaction products in the chamber will be too little, but if too long, too much reaction products will be adhered on the internal walls, making it impossible to obtain the desired results. Therefore, the conditions for seasoning must be determined by trial and error, according to which various seasoning conditions are tested before the product wafer is actually processed. Much time and many wafers are required to determine the seasoning conditions. If the status of the apparatus has been changed, such as when some parts are replaced, the determined seasoning conditions must be reset to correspond to the new status by trial and error.

Next, according to the example disclosed in patent document 2, various values are detected and utilized when monitoring the fluctuation of the apparatus status by multivariate analysis, but there is no consideration on how the fluctuation of the status affects the processing results. Some values being detected may influence the processing results, while other values may not. Therefore, even if the fluctuation of the apparatus status is detected, the processed result is not necessary affected by the fluctuation. The example also lacks to consider how much change in the sensed value affects the processing results to what extent.

### SUMMARY OF THE INVENTION

In consideration of the above problems, the object of the present invention is to provide a plasma processing apparatus and plasma processing method that is capable of monitoring the dispersion of the processing results caused by the fluctuation of the status of the plasma processing apparatus, and capable of determining whether processing is possible or not by detecting the recovery status of the apparatus, for example when the apparatus status is greatly changed by maintenance operation.

The above object is achieved by providing a plasma status detecting means in a processing chamber of a plasma processing apparatus, and storing in a control unit of the processing apparatus the data related to past wafer processing results and plasma status detection data obtained during said past wafer processing, and a relational expression for correlating the two data, thereby utilizing the relational expression and the plasma status detection data obtained at the time of wafer processing to compute a prediction of the processing result after the wafer processing is performed, and monitoring the processing chamber status based on the computed prediction of the processing result.

According further to the present invention, a relational expression correlating the plasma status detection data obtained during product wafer processing and the data related to the processed result of the product wafer is stored in the database, and after product wafer processing is performed, a prediction of the product processing result is computed from the relational expression and the plasma status detection data. In addition, a relational expression correlating the plasma status detection data obtained during dummy wafer processing and the processing result of the product wafer being processed at a close timing is stored in the database, and based on the relational expression and the plasma status detection data obtained by electric discharge of the dummy wafer, a prediction of the processing result supposing that a product wafer has been processed at that time can be computed.

As explained above, according to the present invention, whether the apparatus is ready to provide satisfactory processing to the product wafer or not can be determined based on the computed prediction of the product processing results.

Furthermore, the object of the present invention can be achieved more effectively by storing in the database the above-mentioned data for every type of product being processed by the apparatus.

According to the present invention, the generation of defective product wafers due to apparatus disorder can be prevented by outputting a warning to an operator when the computed prediction of the processing result exceeds a range set in advance.

### BRIEF DESCRIPTION OF THE DRAWINGS

FIG. 1 is a schematic view of a plasma processing apparatus equipped with an apparatus status monitoring system according to the first embodiment of the present invention;

FIG. 2 shows an operation flow according to the first embodiment of the present invention;

FIG. 3 is an example of a display showing the result of operation according to the first embodiment of the present invention;

FIG. 4 shows an operation flow according to the second embodiment of the present invention;

FIG. 5 is an example of a display showing the result of operation according to the second embodiment of the present invention;

FIG. 6 shows an operation flow according to the third embodiment of the present invention;

FIG. 7 is an example of a display showing the result of operation according to the third embodiment of the present invention;

FIG. 8 illustrates an example of product processing utilizing plural processing apparatuses according to the present invention;

FIG. 9 is a schematic cross-sectional view of a semiconductor substrate according to the fourth embodiment of the present invention;

FIG. 10 is an operation flow showing the fourth embodiment of the present invention; and

FIG. 11 is an example of a display showing the result of operation according to the fourth embodiment of the present invention.

### DETAILED DESCRIPTION OF THE PREFERRED EMBODIMENT

Now, the preferred embodiments of the present invention will be explained in detail with reference to the drawings.

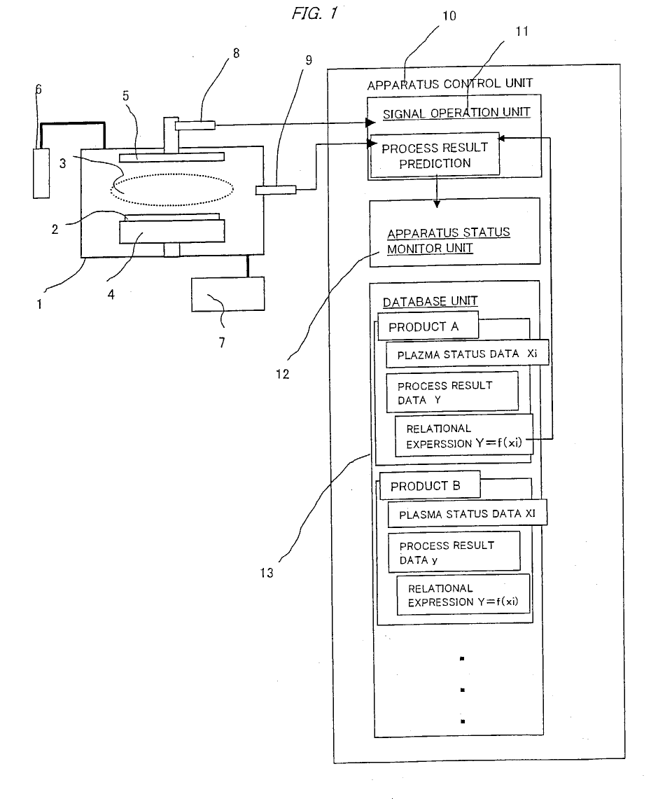

FIGS. 1 through 3 illustrate the first embodiment of the present invention. FIG. 1 shows a plasma processing chamber equipped with an apparatus status monitor system. The plasma processing apparatus according to the present invention comprises a processing chamber 1, a gas supply means 6, a gas evacuation means 7, and an apparatus control unit 10. The processing chamber 1 comprises a sample holder 4, a plasma generating means 5, and plasma status detecting means 8 and 9. The apparatus control unit 10 comprises a signal operation unit 11, an apparatus status monitor unit 12, and a database unit 13.

The processing chamber 1 is equipped with a gas supply means 6 for supplying processing gas into the chamber, and a gas evacuation means 7 for evacuating the processing gas and controlling the pressure within the processing chamber. Further, a sample holder 4 for supporting the sample 2 to be processed and a plasma generating means 5 for generating plasma 3 within the chamber are disposed in the processing chamber. In a semiconductor fabrication apparatus, the sample 2 is a wafer, and in a LCD fabrication apparatus, the sample 2 is a glass plate.

The plasma status detecting means 8 and 9 can be, for example, a current detector or a voltage detector disposed on a path for providing power to the plasma generating means 6, or a current-voltage phase difference detector, a traveling wave detector, a reflected wave detector, or an impedance monitor. Furthermore, it can be a spectrometer disposed in the chamber 1 for detecting the emission of the plasma generated by the plasma generation means 6. The emission spectrometer can be a monochromator for taking out a single wavelength, but it is more preferable to utilize a spectrometer capable of outputting various signals such as emission spectrums corresponding to separated wavelengths. Moreover, the plasma status detecting means 8 and 9 can be means other than those listed above, including a gas flow meter equipped to the gas supply means 6, or a mass spectroscope located in the processing chamber. These status detection means output signals indicating the status of the apparatus at predetermined time intervals or per every predetermined sampling timing.

The plasma processing apparatus control unit 10 comprises a signal operation unit for processing the signals being transmitted from the plasma status detecting means 8 and 9, an apparatus status monitoring unit 12 for notifying the status of the apparatus to the exterior, and a database unit 13 storing data per each type of product being treated by the present apparatus related to the past plasma processing results, the plasma status detection data during execution of the plasma process of the wafer corresponding to the processing result, and the correlation between the plasma status data and the processed dimension or etching rate, for example.

In many cases, a large number of signals are transmitted from the plasma status detecting means 8 and 9. For example, when the means is a spectrometer outputting emission spectrums corresponding to separated wavelengths, the number of status signals being output per every sampling time reaches 1000 to 2000. In order to express the correlation between the many signals and the result of processing, it is best to reduce the number of signals by filtering the signals through a multivariate analysis such as a principle component analysis.

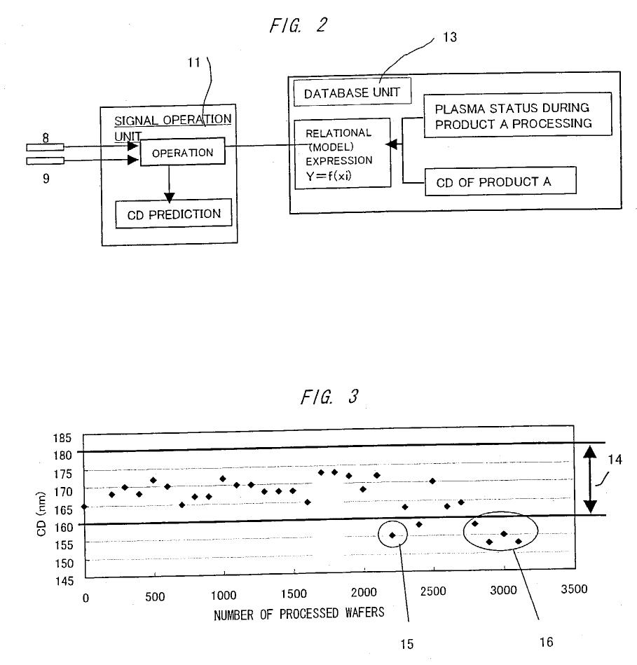

Next, FIGS. 2 and 3 are used to explain an example of how a critical dimension (CD, representative microscopic dimension) is monitored. FIG. 2 shows the operation flow according to the present invention, and FIG. 3 illustrates an example of how the operation results are displayed. The database unit 13 stores the plasma status detection data during etching for a predetermined past period of time, the CD value which is the processing result, and the correlation expression (model expression) of the two data, for all the kinds of products being processed in the processing chamber 1. When the fabrication of a certain product (which we will refer to as product A) is started, the signal operation unit 11 retrieves the relational expression of the plasma status detection data and the critical dimension (processing result) from the database, and when the current etching process is terminated, computes the critical dimension using the model expression and the plasma status detection data transmitted from the plasma status detecting means 8 and 9.

For example, the processing of electrodes in a gate wiring requires highly accurate dimension management, since the dimension of the wiring width will directly affect the operation rate of the device. Usually, the critical dimension is inspected following the etching process using a scanning electron microscope for dimension measurement (CD-SEM) When the critical dimension is inspected using the CD-SEM, it is impossible to inspect all the wafers being processed because of the inspection time required for inspecting a single wafer by the CD-SEM, so typically only a single wafer per several lots is inspected. If the plasma status of the apparatus is somehow changed just after a single wafer is inspected using the CD-SEM and the change of status causes the critical dimension of the product to be deteriorated, the operator may not notice the abnormality until the next dimension measurement inspection, causing a number of defective products to be created during that time. With the wafer dimension enlarged and wafer prices rising, the loss caused by such defection is immeasurable.

According to the present invention, the critical dimension can be predicted by calculation directly after the processing of the wafer, and the result can be displayed as shown in FIG. 3. For example, a certain threshold l4 can be set for the critical dimension, and a warning can be output when the critical dimension exceeds the threshold as shown by marks 15 and 16, to thereby suppress the loss caused by the generation of defected wafers to a minimum. The warning can also be utilized to perform maintenance operation at an appropriate timing. The warning can be an alarm such as a buzzer, a display on the operation panel, or a display on a personal computer of the operator.

It is effective to divide the warning into several levels, depending for example on how many times in a row the threshold was exceeded or how many warnings have been accumulated. The warning levels can be utilized to operate the apparatus efficiently. For example, if the critical dimension exceeds the threshold once but returns to the threshold range in the next wafer processing, a minor warning is output and the process is continued, but if the critical dimension exceeds the threshold three times in a row or if the accumulated number of times the critical dimension exceeded the threshold reaches a determined number, further processing is prohibited and a maintenance operation is started. The correlational expression stored in the database should preferably be updated at a predetermined timing to an expression computed based on new data.

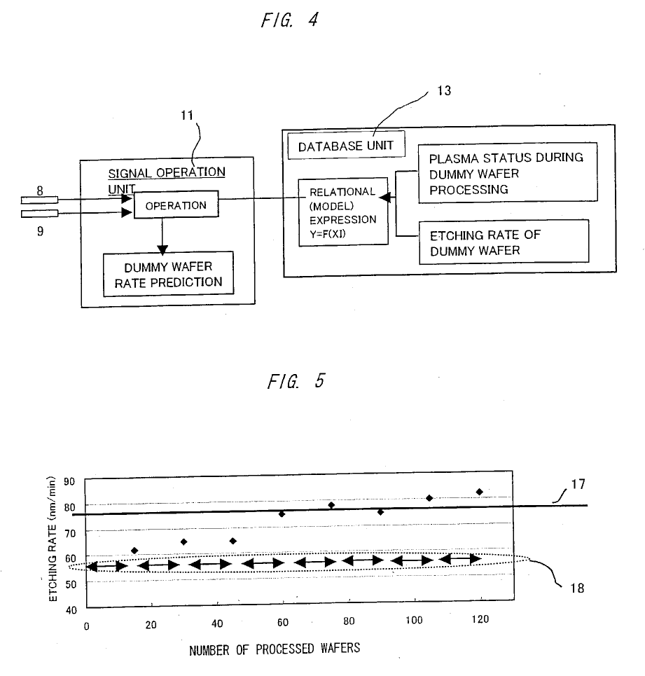

Next, FIGS. 4 and 5 are referred to in explaining the second embodiment of the present invention. As the number of processed wafers increases, the reaction products generated during etching and adhered on the internal walls of the etching apparatus gradually increase. When the accumulated reaction products on the walls form a film having a certain thickness, the adhered substances may be detached from the walls and fall on the processed wafer, causing short circuit. In order to prevent this from happening, the chamber must be released to the atmosphere periodically to remove the adhered contaminants using water or organic solvents. This cleaning process is so-called wet cleaning. After wet cleaning, the internal wall surfaces of the apparatus are in an activated state with water molecules adhered on the walls and the accumulated reaction products completely removed. As a result, the emission of water molecules to the processing chamber and the adhesion and detachment of the reaction products become significant, and directly after wet cleaning the CD and the etching rate fluctuate along with the processing of wafers. If the processing dimension is very fine, the influence of such fluctuation to the processed product is significant. The present invention provides an effective method for monitoring this fluctuation status, and can be applied to determine whether the apparatus is ready to process products after wet cleaning. The present embodiment explains an example for applying the present invention to the monitoring of etching rates. FIG. 4 shows the flow of operation performed according to the present embodiment, and FIG. 5 is a display example showing the result of the operation.

The database unit 13 stores a plasma status detection data measured during past etchings of dummy wafers used for measuring the etching rate, the measured etching rate (processing results), and the relational expression (model expression) obtained from the two data.

After wet cleaning, a dummy wafer for measuring the etching rate is etched to confirm the etching performance. At this time, the relational expression of the plasma status detection data and the etching rate of the dummy wafer is retrieved by the signal operation unit 11, where the current etching rate is computed using the model expression and the data transmitted from the plasma status detection means 8 and 9 when the etching of the dummy wafer is completed. Normally, the etching rate is computed by measuring the etching residual film using a film thickness measurement unit after the etching process is completed.

The rate-measuring wafers are expensive even though they are dummy wafers, so typically one rate-measuring wafer is processed per several Si bare wafers being processed. In other words, the rate measuring dummy wafer is inserted with certain intervals to the Si bare wafers, which are etched for rate measurement. However, the processing of product wafers cannot be started until the result of the rate measurement is output and the recovery of the etch performance is confirmed. If as a result of inspection the etch rate is not satisfactory, the processing of Si bare wafers with the dummy wafers inserted at certain intervals must be performed again for further measurement.

Etching rate measurement requires much time, including the time required for transferring the wafers to the inspection apparatus and for inspection. If the etching apparatus is stopped of product processing during this time, the productivity is greatly deteriorated. However, according to the present invention, the computed etching rate can be displayed without delay after the etching process is performed, as shown in FIG. 5. In FIG. 5, the plotted points show the computed and predicted rate, and the portions illustrated by arrows 18 show where the Si bare wafers were being etched. For example, an etching rate 17 is set where product processing becomes possible, and if the etching rate enters the range of the set ratio 17, a notice informing the operator that product processing is now possible can be output. Thus, highly efficient production is realized. The method for notifying that production is now ready can be the sound of a buzzer, or a message displayed on the operation panel or the screen of the personal computer of the operator.

Furthermore, the above-mentioned method of monitoring the fluctuation of the etching rate can be applied for monitoring the change in performance during long period of use of the apparatus. According to the present method, the etching rate can be predicted just by etching the rate-measuring dummy wafer and does not require film thickness inspection, so by processing the rate-measuring dummy wafers at predetermined time intervals, such as four times a day, the performance of the apparatus and whether product processing is possible or not can be judged without delay. The present method can also be utilized to perform maintenance at an appropriate timing, such as by executing maintenance when the desired etching rate can not be achieved.

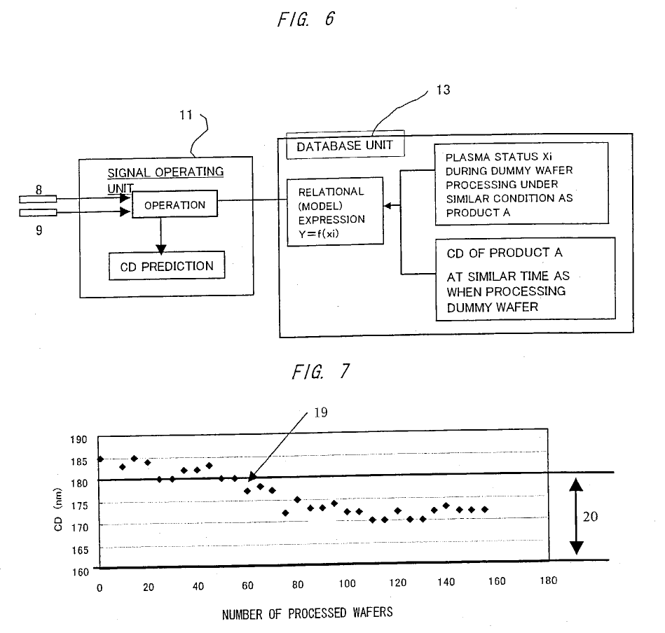

Next, FIGS. 6 and 7 are used to explain the third embodiment of the present invention. As mentioned in the description of the second embodiment, after wet cleaning, the residual reaction products adhered on the internal walls of the processing chamber are completely removed, leaving the wall surfaces activated with adhesion. Thus, removal of the reaction products during etching becomes significant. Therefore, the CD being output is somewhat thick by the etching process performed directly after the wet cleaning, and as the number of processed wafers increase, the CD becomes thinner and stabilizes. The electrode processing of the gate wiring requires very accurate dimension management since the dimension of the wiring thickness affects the operation rate of the device directly. If the desired CD cannot be realized, the processed wafer becomes defective. Thus, normally after wet cleaning, a start-up operation so-called seasoning is executed where a certain number of dummy wafers are etched.

Conventionally after seasoning is performed for a certain number of wafers, a single product wafer is etched, and the dimension of which is inspected thereafter by CD-SEM. If the dimension is within a determined range, the processing of products can be started, but if not, seasoning is performed again where a certain number of dummy wafers are etched before etching a single product wafer, the dimension of which is inspected again, and the same process is performed over and over until the dimension being checked fits within the predetermined range. Since the following process cannot be started until the inspection result comes out, a long period of time is wasted after the wet cleaning. Furthermore, if the predetermined dimension cannot be achieved by the first product wafer, the product wafer(s) being etched for testing is wasted.

The present embodiment can be effectively applied for monitoring the CD and for determining when product processing can be restarted based on the monitored data. FIG. 6 shows the operation flow performed according to the present embodiment, and FIG. 7 shows an example of the display of the result of operation. With regard to the product (for example, product A) for which CD monitoring is to be performed, the processing of dummy wafers are performed under similar conditions as processing product A and at a similar time as when the etching of a few product wafers are performed during a certain period of time, and based on the plasma status detection data of the dummy wafer for which etching is performed and the CD of the product wafer being processed at a similar time, a relational expression (model expression) is created and stored in the database unit 13. The term “at a similar time” preferably refers to a continued process, but can include a difference within a few hours.

The seasoning process (etching of dummy wafers) is performed after wet cleaning, and during seasoning, the signal operation unit 11 retrieves the relational expression of the CD of the product being etched during a predetermined period of time and the plasma status detection data related to the dummy wafers being etched at a similar time as when the products are etched, and performs computation of the CD for each wafer being processed during seasoning using the model expression and the data transmitted from plasma status detection means 8 ad 9 after etching of the wafer is performed.

Even though the etched wafer is a dummy wafer, the relational expression shows the CD of the product being etched at a similar time as when the dummy wafer for detecting the plasma status is etched, so the computed value becomes a prediction of the etched result supposing that the product wafer is etched at that time. It is preferable that the dummy wafers are formed of the same material as the product wafer, but in the etching of a polysilicon product such as a gate electrode, a bare Si wafer can be used to achieve the similar plasma status detection data and to output a satisfactory prediction.

In other words, according to the present embodiment, the prediction of the CD value if product A is etched supposedly at that time can be computed and displayed as shown in FIG. 7 based on the data from the dummy wafer. Moreover, by predicting the processing results, whether or not to start processing the product wafers can be determined without performing inspection using CD-SEM. For example, a certain CD value 20 is set according to which product processing becomes possible, and when the predicted CD enters the range of the set CD value 20 (shown by arrow 19 of FIG. 7), a notice can be output notifying the operator that the processing of products may be started. The present embodiment enables to realize a significantly efficient production of wafers compared to the conventional method where the decision on whether to restart production is performed based on seasoning and CD inspection.

The present method for monitoring the fluctuation of the CD is not only applied for monitoring the processing after wet cleaning, but can be applied for other situations where the reaction products within the processing chamber are increased significantly, such as when the processing of a product having a larger etching area is started after the processing of smaller products. When the present invention is applied to such situation, the result of processing, or the CD, of the product with the larger area can be predicted by etching bare Si dummy wafers, and the determination on whether or not to start processing the actual products is thereby made possible. The present method enabling to determine whether or not to start actual processing just by etching dummy wafers and not by etching actual product wafers is very advantageous in that it saves time and cost compared to the conventional method.

The present method for monitoring the fluctuation of the CD is also effective for monitoring the fluctuation of the performance of the apparatus during long period of use of the apparatus. According to the present method, the CD value can be predicted just by etching the dummy wafer, so by processing the dummy wafers at predetermined time intervals, such as four times a day, the performance of the apparatus at that time and whether product processing is possible or not can be judged without delay.

As the processing of products is advanced causing residual products to be adhered on the internal walls of the apparatus or parts to be consumed, the status of the plasma is changed, and as a result, the plasma processing result is changed. Therefore, it is necessary to predict the result of the process performed to the product wafer based on the plasma status of the dummy wafer processing, as explained in the third embodiment. The passing of time causes increase in the residual products being adhered on the walls and advanced consumption of parts, so in order for the prediction to be as precise as possible, the time-lag between product wafer processing and dummy wafer processing should be as short as possible. In the present invention, data are collected intentionally to be stored in the database, so dummy wafer processing should preferably be performed directly before or after the processing of the product wafer.

However, the dummy wafer processing should not necessarily be performed directly before or after the processing of the product, and the range of the acceptable time-lag is determined by the required product accuracy. In other words, the acceptable range is determined by how much the status of the walls and the consumable parts differ by etching a single wafer, and how sensitive the device being processed is to the change in status. The acceptable time range differs between products being insensitive to the change in the dimension that causes the electric properties to be varied slightly, and products being sensitive to such change.

Actually, when etching polysilicon with a 0.18 μm width, the CD could be predicted with good accuracy even if the time differs for a few hours to even over ten hours.

According to the present embodiment, when etching a polysilicon with a 0.18 μm width, the prediction was as accurate as ±5 nm even when there was a ten hour time difference between the product wafer processing and dummy wafer processing. The acceptable time range is determined by how much the status of the walls and the consumable parts differ by etching a single wafer, and how sensitive the device being processed is to the change in status, so if better accuracy is required, the data should be collected at a closer time.

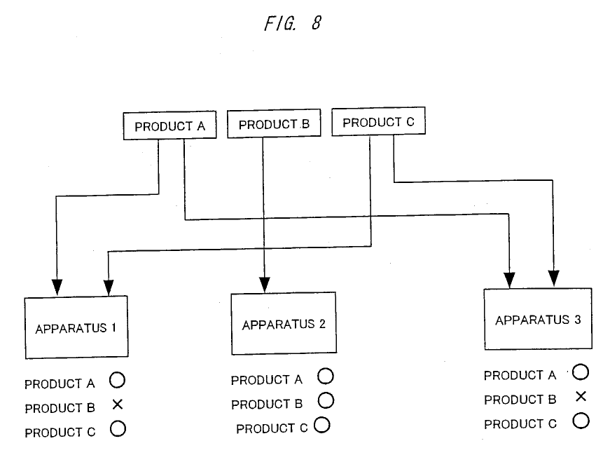

Furthermore, such method for monitoring the fluctuation of the CD is very effective when a variety of small-volume products are produced in a mixed flow. For example, when products A, B and C having different dimension accuracies are to be processed using the same apparatus as shown in FIG. 8, there may be cases where the apparatus is ready for processing products A and C but not for product B, since the acceptable range of accuracy of product B is strict. In order to prevent occurrence of wafer defects, the status of the apparatus is monitored by executing the above-mentioned etching rate inspection and CD inspection at predetermined time intervals, to determine whether processing is possible or not. However, these inspections require expensive testing wafers and take up much time, deteriorating the productivity. In the above case where various products are to be processed, the inspection is performed to determine whether the apparatus is ready for processing the product having the most strict accuracy requirement, in this case, product B. Therefore, if the test result does not satisfy the requirements for processing product B, the apparatus is stopped and maintenance is performed thereto even if the apparatus is still capable of processing products A and C. If many products A and Care still waiting to be processed when the apparatus is stopped, the productivity of the whole production line is deteriorated.

However, by applying the present method for operating the production line, effective production management is realized. By storing to the database the relational expression of the plasma status detection data of the dummy wafer and the CD (the result of the process) for each of the products A, B and C, the present method can be applied to determine which product is ready for processing by the apparatus at that time by etching a dummy wafer. If only product B is not ready for processing, the processing of only product B can be prohibited while processing of products A and C are continued. For example, if the production line comprises apparatuses 1, 2 and 3 capable of providing similar processes, and the processing conditions of apparatuses 1 and 3 has been shifted so that product B could not be processed thereby, the productivity of the whole line will be deteriorated if both apparatuses 1 and 3 are stopped for maintenance and only apparatus 2 is utilized for processing the products. So according to the present invention, products A and C which can still be processed by apparatuses 1 and 3 are sent to apparatuses 1 and 3 for processing while product B is processed only by apparatus 2, thereby preventing the productivity from slowing down. When there are fewer products to be processed, the apparatuses 1 and 3 can be stopped for maintenance. Thus, according to the present invention, the appropriate apparatuses for processing each product can be selected according to their performances at that time without having to perform inspection of the result of product processing and without forming defective products, and the production line is thereby operated efficiently.

Furthermore, the present invention can also be applied to the processing result of the dummy wafer for performance evaluation. As explained in the description of embodiment 2, the dummy wafer for measuring the etching rate is expensive since the dummy wafer has a film formed of the same material as the product wafer deposited on a Si substrate. The processing of inexpensive bare Si wafers, for example, are performed at a time close to when the etching of a dummy wafer for measuring the etching rate is performed during a certain period of time, and based on the plasma status detection data of the bare Si wafer for which etching is performed and the etching rate measured by the dummy wafer for measuring the etching rate processed at a similar time, a relational expression (model expression) is created and stored in the database unit 13. By preparing such model expression, the apparatus performance can be evaluated using an inexpensive bare Si wafer instead of the expensive dummy wafer for rate measurement. In other words, the present embodiment achieves the same advantageous effects as those achieved by embodiment 2 but by using a more inexpensive wafer.

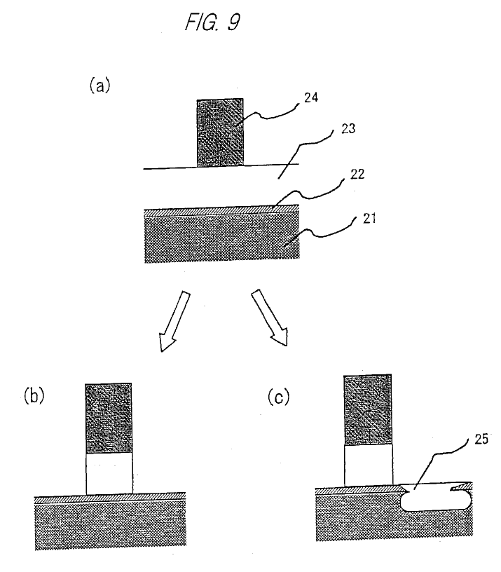

FIGS. 9 through 11 are used to explain the fourth embodiment of the present invention. The present embodiment explains the example where the present invention is applied to monitoring the fluctuation of the etching rate, which is especially effective in monitoring the fluctuation of the etching rate of a base oxide film when processing gate electrodes. FIG. 9 is a schematic cross-sectional view of the processing of a gate electrode explaining the present embodiment. Here, an example is explained where the gate electrode is created by a single layer film of polysilicon. In FIG. 9, reference number 21 is a silicon substrate, and 23 is a polysilicon film deposited on the substrate 1 by CVD (chemical vapor deposition) and the like, which constitutes a gate electrode. Reference number 22 is a gate oxide film, and 24 is a photoresist having openings formed to the areas where the etching process is to be performed.

The etching of a gate electrode is not performed by etching polysilicon 23 at once under a fixed etching condition, but rather, comprises the steps of 1) a main etching step where high speed etching is performed until there remains a thin polysilicon layer having a thickness of a few score nm; 2) a so-called just etching step of completely etching the polysilicon 23, wherein the etching rate of the base gate oxide film 22 is smaller than in the main etching step, that is, the gate oxide film is hardly etched when the polysilicon is completely etched; and 3) a so-called over-etching step where the uneven portions or the residual portions of the substrate are etched, wherein the etching rate of the base gate oxide film 22 is also small.

According to conditions for steps 2 and 3, the etching rate of the oxide film is extremely small, but since the gate oxide film is very thin, having a thickness of approximately 1 nm or a few nm, when the etching rate fluctuates and increases, the gate oxide film 22 may be etched locally and may disappear, creating a through-hole to the Si substrate. According to etching conditions of steps 2 and 3, the etching rate of the gate oxide film is low but the etching rate of the base Si is high, so when there is a through hole formed to the gate oxide film, the Si substrate 21 positioned under the gate oxide film 22 is etched as shown in 25, creating a defective device.

In order to prevent the formation of through holes to the gate oxide film, it is typical to test the etching rate of the oxide film at predetermined time intervals, such as once a day. The etch rate test is performed by actually etching a rate measuring wafer having an oxide silicon film deposited on a Si substrate. When some form of change occurs to the plasma condition of the apparatus causing the rate to increase between rate tests, the product processing is performed without noticing the through-holes formed to the gate oxide film until the next rate test is performed. As a result, many defective wafers are created by the process, and the loss mounts up to an immense amount. Furthermore, the wafer used for rate testing is expensive for a test wafer, since a silicon oxide film must be deposited on a Si substrate. If it is possible to monitor the fluctuation of the etching rate of the gate oxide film not by performing rate tests but by simply monitoring the plasma status detection data during product processing, the cost spent on expensive rate measuring wafers can be saved, and the cost related to generating defective products can also be saved, the effect is enormous.

The gate oxide film 22 is etched when the polysilicon 23 deposited on the film 22 is completely etched, and through-holes may be formed to the gate oxide film, causing the areas of the Si substrate 21 to be etched (25), but the generation of through-holes is difficult to recognize by measuring the rate of the actual product. However, according to the present invention, the etching rate of the dummy wafer is utilized as the bases of determining whether the product wafer can be processed or not, so the possible generation of pinholes can be determined without actually inspecting the product.

The present embodiment has effects that differ from those related to ordinary etch rate prediction, since the formation of through-holes, thus the generation of defective wafers, cannot be evaluated as actual measurable values like etching volume and etching rate. The present embodiment is effective when using the etching volume and etching rate of the dummy wafer as the bases of evaluation.

The present embodiment can be applied not only to the gate oxide film but also to the prediction of the etching rate of films deposited above or below the film being processed, including prediction of the etching rate of a resist mask or the etching rate of a hard mask.

When the object layer is being etched, the mask layer is also etched. The ratio of selectivity of the object layer and the resist or hard mask material is selected so that the etching rate of the mask is smaller than the etching rate of the object layer, but it is difficult to reduce the etching rate of the mask to zero. Therefore, if the etching rate fluctuates and the rate is increased, the mask is etched so that when the etching step is terminated, the mask will have a somewhat shrunk shape with the shoulder portions etched. Thus, the shoulders of the polysilicon are also etched and the performance of the produced device is deteriorated. Also according to this case, the mask is not the object of the etching process but is etched as a result of the process, so the etching quantity of the mask should be determined based on the etching quantity and the etching rate of a test dummy tested to determine the etching rate of a rate-measuring wafer with the current mask material.

The determination process is simple when a single layer film is involved, but the determination is more complicated when a multilayer film such as W (tungsten)/polysilicon is involved. The conditions for etching tungsten differs from the conditions for etching polysilicon, so the etching rates according to the two conditions also differ. In a normal inspection procedure, the etching rate of the mask is inspected according to the etching conditions (for etching both tungsten and then polysilicon) at predetermined time intervals (such as once a day), but when rate abnormality is observed, there is no way of knowing which etching condition caused the abnormality. However, according to the present invention, the data related to the measured etching rate of tungsten and polysilicon and the plasma status are stored in the database, so the etching rates of the tungsten layer and the polysilicon layer can be predicted independently supposing that a rate measuring dummy wafer is etched. Thus, abnormality can be corrected without delay.

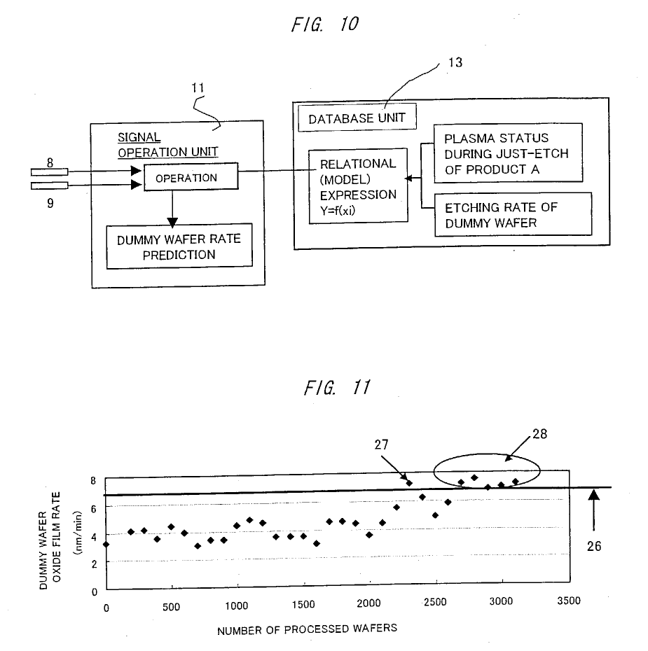

FIG. 10 shows the flow of the operation performed according to the present embodiment, and FIG. 11 shows an example of a display of the operation result. The etching rate is measured in advance by etching a rate measuring wafer having a film formed of the same material as the gate oxide film deposited on the surface, under a condition similar to the just-etching step or the over-etching step of product A and at a similar time as when the wafer of product A is etched. The term “at a similar time” preferably refers to a continued process, but can include a difference within a few hours. Moreover, the etching condition is not necessarily equal to that of the just-etching step or over-etching step, but the condition can be set so that the oxide film rate is set higher so that the oxide film etching rate fluctuation is exaggerated when the dummy wafer is etched, or the condition may be set so that the etching time is elongated so that the rate can be calculated easily, to make the following determination easier. This is because the etching rate of the oxide film in the just-etching step or over-etching step is so little so that fluctuation is difficult to observe.

The database unit 13 stores the etching rate data obtained by etching the rate-measuring dummy wafer, the plasma status detection data of the product wafer processing, and the relational expression (model expression) obtained from the two data. The plasma status detection data of the product wafer is obtained from the plasma where the etching of polysilicon is completed and etching of gate oxide film is underway, so the model expression is formed using data based on the over-etching condition or data based on the timing after polysilicon etching has been completed or prior to completing just-etching. When the processing of product A is underway, the signal operation unit retrieves from the database unit the relational expression of the plasma condition detection data and the etching rate data of dummy wafer etching, and when the etching process of product A is completed, the data sent from the plasma status detecting means 8 and 9 are computed based on the relational expression retrieved to the signal operation unit from the database unit, according to which the etching rate is calculated. The calculated value shows the etching rate of a dummy wafer having a film formed of the same material as the gate oxide film that is supposedly etched at this time under the conditions similar to the just-etching step or the over-etching process of product A.

As explained, according to the present invention, the etching rate of a dummy wafer supposedly etched at that time can be computed by calculation and displayed on a screen without having to actually etch dummy wafers, as illustrated in FIG. 11. By setting a maximum value to the calculated etching rate of the dummy wafer, and by outputting a warning when the computed value exceeds the set range 26, the loss caused by producing defective wafers can be suppressed to a minimum, and maintenance can be performed at an appropriate timing. Similar to the first embodiment, it is effective to divide the warning into several levels, depending for example on how many continuous times the threshold was exceeded or how many warnings have been accumulated. For example, if the computed etching rate exceeds the threshold once but returns to the threshold range in the next processing as shown by arrow 27, a minor warning is output and the process is continued, but if the computed etching rate exceeds the threshold three times in a row or if the accumulated number of times the computed etching rate exceeded the threshold reaches a determined value, further processing is prohibited and a maintenance operation is started.

According to the present invention, the process results can be predicted based on a plasma status detection data obtained from the wafer processing chamber after the current process is completed and utilizing the relational expression correlating the past wafer processing results and the plasma status detection data obtained during the past wafer processing. Thus, the defects that may be caused by the fluctuation of the processing statuses are noticed without delay, and the loss caused by the generation of defective wafers during the varied processing status is minimized. According further to the present invention, the timing for performing maintenance of the apparatus can be set appropriately.

According further to the present invention, based on the plasma status detection data utilizing the discharge of dummy substrates, the processing result obtained if a product wafer is supposedly processed at that time can be predicted by calculation. Therefore, based on the prediction, whether or not a desired processing result can be achieved is determined without actually processing the product and inspecting the same. Thereby, expensive product wafers will not be wasted, and the waiting time for inspection or the work related to the inspection process can be saved.

What is claimed is:

1. A plasma processing apparatus comprising a control unit and a processing chamber for performing a plasma processing:
the processing chamber comprising a plasma status detecting means for detecting the processing status in the processing chamber and outputting plural output signals; and
the control unit equipped with a function to store data related to past wafer processing results, plasma status detection data obtained during said past wafer processing, and a relational expression correlating the two data; a function to compute a prediction of the processing result based on said relational expression and the detected data of the processing chamber status transmitted from the plasma status detecting means; and a function to evaluate the processing chamber status based on the computed prediction of the processing result.

2. A plasma processing apparatus according to claim 1, further comprising:
providing processing to a product wafer; and
the control unit storing data related to past product wafer processing results, plasma status detection data obtained during said past product wafer processing, and a relational expression correlating the two data; computing a prediction of the processing result based on said relational expression and the detected data of the plasma status transmitted from the plasma status detecting means during product wafer processing; and evaluating the processing chamber status based on the computed prediction of the processing result.

3. A plasma processing apparatus according to claim 1, further comprising:
providing processing to a dummy wafer; and
the control unit storing data related to past dummy wafer processing results, plasma status detection data obtained during said past dummy wafer processing, and a relational expression correlating the two data; computing a prediction of the processing result based on said relational expression and the detected data of the plasma status transmitted from the plasma status detecting means during dummy wafer processing; and evaluating the processing chamber status based on the computed prediction of the processing result.

4. A plasma processing apparatus according to claim 1, further comprising:
providing processing to a dummy wafer at a similar time and under a similar condition as when a product wafer is processed; and
the control unit of the processing chamber storing data related to said dummy wafer processing results, plasma status detection data obtained during processing of the product wafer, and a relational expression correlating the two data; computing a prediction of the processing result supposing that a dummy wafer is processed at that time based on said relational expression and the detected data of the plasma status transmitted from the plasma status detecting means during product wafer processing; and evaluating the processing chamber status based on the computed prediction of the processing result.

5. A plasma processing apparatus according to claim 1, wherein
when the prediction of the processing result computed based on the relational expression and the status detection result exceeds a predetermined value, outputting or displaying a notice announcing the same is output or displayed.

6. A plasma processing apparatus according to claim 1, wherein
the processing result information and the relational expression corresponding to every type of product being processed by said plasma processing apparatus are stored.

7. A plasma processing method applied to the plasma processing apparatus according to claim 2, comprising:
during processing of the product wafer, if the computed prediction of the processing result is equal to or greater than a threshold being set in advance, performing no further product wafer processing.

8. A plasma processing method applied to the plasma processing apparatus according to claim 3, comprising:
during processing of the dummy wafer, if the computed prediction of the processing result is equal to or greater than a threshold being set in advance, performing no further dummy wafer processing.

9. A plasma processing method applied to the plasma processing apparatus according to claim 4, comprising:
during processing of the dummy wafer under a similar condition as processing a product wafer, if the computed prediction of the processing result is equal to or greater than a threshold being set in advance, performing no further product wafer processing.

10. A plasma processing apparatus according to claim 1, further comprising:
providing processing to a dummy wafer; and
the control unit storing data related to past dummy wafer processing results performed under approximate conditions, plasma status detection data obtained at a similar time as said past dummy wafer processing, and a relational expression correlating the two data; computing a prediction of the processing result based on said relational expression and the detected data of the plasma status transmitted from the plasma status detecting means during dummy wafer processing; and evaluating the processing chamber status based on the computed prediction of the processing result.
